(19) United States
(12) Patent Application Publication
(10) Pub. No.: US 2026/0096326 A1
(43) Pub. Date: Apr. 2, 2026

(54) DISPLAY PANEL AND DISPLAY DEVICE

(71) Applicant: Shanghai Tianma Micro-electronics Co., Ltd., Shanghai (CN)

(72) Inventors: Qingling MENG, Shanghai (CN); Shanshan YANG, Shanghai (CN); Yuchuan PAN, Shanghai (CN); Zhiyuan ZHANG, Shanghai (CN); Fan TIAN, Shanghai (CN); Xiongping LI, Shanghai (CN)

(21) Appl. No.: 19/239,210

(22) Filed: Jun. 16, 2025

(30) Foreign Application Priority Data
Sep. 30, 2024 (CN) 202411396210.7

(51) Int. Cl. H10K 59/50; G02F 1/153; H10K 59/35; H10K 59/40; H10K 59/80

(52) U.S. Cl. CPC H10K 59/50; G02F 1/153; H10K 59/353; H10K 59/40; H10K 59/8792

(57) ABSTRACT

The disclosure provides a display panel and a display device. The display panel includes a substrate; a light-emitting unit layer disposed on one side of the substrate, where the light-emitting unit layer includes a plurality of main pixels and a plurality of auxiliary pixels; and an auxiliary functional layer disposed on a side of the light-emitting unit layer away from the substrate, where the auxiliary functional layer includes a first functional component, the first functional component is arranged corresponding to an auxiliary pixel. In a first state, at least part of the first functional component is light-shielding.

### CROSS-REFERENCE TO RELATED APPLICATION

This application claims the priority of Chinese Patent Application No. 202411396210.7, filed on Sep. 30, 2024, the content of which is incorporated herein by reference in its entirety.

### TECHNICAL FIELD

The present application relates to the field of display technology, and in particular to a display panel and a display device.

### BACKGROUND

With the continuous development of network technology, more and more users need to perform operations such as account transactions on display devices. However, when users perform the above operations in public places, it is easy for personal information to be leaked when they access bank accounts, pay bills, or enter personal information, which in turn leads to the risk of identity theft and privacy infringement. Therefore, display devices with anti-peeping functions have received more and more attention.

For display panels, a grating structure is usually set on the light-emitting side of the display panel to form an anti-peeping film. The grating structure may block the light emitted from a large viewing angle, thereby changing the large viewing angle of the screen to a narrow viewing angle to achieve an anti-peeping function. However, after the grating structure is set in the display panel, the display panel may only be in the anti-peeping mode all the time. When multiple people need to watch the screen at the same time, it will cause inconvenience in use, thereby affecting the user experience.

### SUMMARY

In view of the foregoing, embodiments of the present disclosure provide a display panel and a display device.

Embodiments of the present application provide a display panel, including a substrate; a light-emitting unit layer disposed on one side of the substrate, where the light-emitting unit layer includes a plurality of main pixels and a plurality of auxiliary pixels; and an auxiliary functional layer, disposed on a side of the light-emitting unit layer away from the substrate, where the auxiliary function layer includes a first function part, and the first function part is arranged corresponding to the auxiliary pixel. In a first state, the first functional component is light-shielding.

Embodiments of the present disclosure further provide a display device including a display panel, where the display panel includes a substrate; a light-emitting unit layer disposed on one side of the substrate, where the light-emitting unit layer includes a plurality of main pixels and a plurality of auxiliary pixels; and an auxiliary functional layer, disposed on a side of the light-emitting unit layer away from the substrate, where the auxiliary function layer includes a first function part, and the first function part is arranged corresponding to the auxiliary pixel. In a first state, the first functional component is light-shielding.

Other features of the present disclosure and advantages thereof will become apparent from the following detailed description of exemplary embodiments of the present disclosure with reference to the accompanying drawings.

### BRIEF DESCRIPTION OF THE DRAWINGS

In order to illustrate the technical solutions in accordance with the embodiments of the present disclosure more clearly, the accompanying drawings to be used for describing the embodiments are introduced briefly in the following. It is apparent that the accompanying drawings in the following description are only some embodiments of the present disclosure. Persons of ordinary skill in the art can obtain other accompanying drawings in accordance with the accompanying drawings without any creative efforts.

FIG. 1 is a top view of a display panel in accordance with an embodiment of the present disclosure;

FIG. 2 is an enlarged top view of a portion (corresponding to the dotted line frame area in FIG. 1) of a display panel in accordance with an embodiment of the present disclosure;

FIG. 3 is a partial cross-sectional view along the AA direction in FIG. 2;

FIG. 4 is a schematic diagram of light in the second state in the embodiment shown in FIG. 3;

FIG. 5 is a schematic diagram of light in the first state of the embodiment shown in FIG. 3;

FIG. 6 is a partially enlarged top view of a display panel in one state in accordance with an embodiment of the present disclosure;

FIG. 7 is a partially enlarged top view of a display panel in another state in accordance with an embodiment of the present disclosure;

FIG. 8 is a partial cross-sectional view along the BB direction in FIG. 7;

FIG. 9 is a partial enlarged top view of a display panel in accordance with an embodiment of the present disclosure;

FIG. 10 is a cross-sectional view of a display panel in accordance with an embodiment of the present disclosure;

FIG. 11 is a cross-sectional view of another display in accordance with an embodiment of the present disclosure;

FIG. 12 is a cross-sectional view of another display panel in accordance with an embodiment of the present disclosure;

FIG. 13 is a cross-sectional view of another display panel in accordance with an embodiment of the present disclosure;

FIG. 14 is a cross-sectional view of yet another display panel in accordance with an embodiment of the present disclosure;

FIG. 15 is a schematic top view of a touch electrode layer in a display panel in accordance with an embodiment of the present disclosure;

FIGS. 16 to 18 are several cross-sectional views of a display panel in accordance with an embodiment of the present disclosure;

FIGS. 19 and 20 are respectively partial enlarged top views of a display panel in accordance with an embodiment of the present disclosure;

FIGS. 21 to 24 are cross-sectional views of a display panel including light in accordance with an embodiment of the present disclosure; and

FIG. 25 is a schematic diagram of a display device in accordance with an embodiment of the present disclosure.

### DETAILED DESCRIPTION

To make the aforementioned objective, features, and advantages of the present disclosure more obvious and easy to understand, the present disclosure will be further described below in conjunction with the accompanying drawings and embodiments.

It should be noted that specific details are described in the following description to facilitate a thorough understanding of the present disclosure. However, the present disclosure may be implemented in a variety of other ways different from those described herein, and those skilled in the art may make similar generalizations without violating the connotation of the present disclosure. Therefore, the present disclosure is not limited to the specific embodiments disclosed below.

The terms used in the embodiments of the present disclosure are only for the purpose of describing specific embodiments and are not intended to limit the present disclosure. The singular forms “a”, “said” and “the” used in the embodiments of the present disclosure and the appended claims are also intended to include plural forms unless the context clearly indicates other meanings.

It should be noted that the directional words such as “upper”, “lower”, “left”, and “right” described in the embodiments of the present disclosure are described at the angles shown in the drawings and should not be understood as limiting the embodiments of the present disclosure. In addition, in the context, it should also be understood that when it is mentioned that an element is formed “on” or “under” another element, it may not only be formed directly “on” or “under” another element, but also be formed “on” or “under” another element indirectly through an intermediate element.

Furthermore, the example embodiments may be implemented in a variety of forms and should not be construed as being limited to the embodiments described herein. On the contrary, these embodiments are provided to make the present disclosure more comprehensive and complete, and to fully convey the concept of the example embodiments to those skilled in the art. The same reference numerals in the figures represent the same or similar structures, and thus their repeated descriptions will be omitted. The words expressing position and direction described in the present disclosure are illustrated with the accompanying drawings as examples, but may also be changed as needed, and these changes are included in the scope of protection of the present disclosure. The drawings of the present disclosure are merely used to illustrate the relative position relationship, and the layer thickness of certain parts is exaggerated for easy understanding. The layer thickness in the drawings does not represent the proportional scale of the actual layer thickness. In the absence of conflict, the embodiments of the present disclosure and the features in the embodiments may be combined with each other. The drawings of the embodiments in this disclosure use the same markings of the drawings. In addition, the similarities between the embodiments are not repeated.

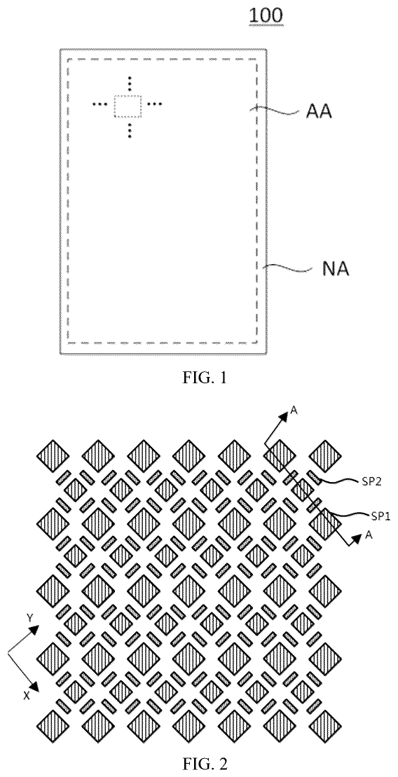

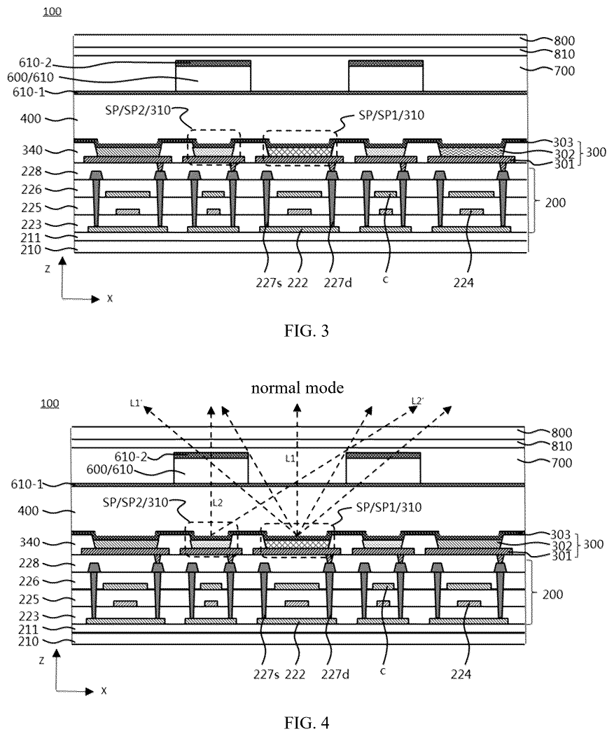

Refer to FIGS. 1 to 3, FIG. 1 is a top view of a display panel in accordance with an embodiment of the present disclosure, FIG. 2 is an enlarged top view of a portion of the display panel (corresponding to the dotted frame area in FIG. 1) in accordance with an embodiment of the present disclosure, and FIG. 3 is a partial cross-sectional view along the AA direction in FIG. 2, where the cross-section is perpendicular to a plane where the display panel is located.

In some embodiments, the display panel 100 is divided into a display area AA and a non-display area NA surrounding the display area AA. It may be appreciated that the dotted box in FIG. 1 is used to illustrate the boundary between the display area AA and the non-display area NA. The display area AA is an area of the display panel used to display images, and generally includes a plurality of pixels SP arranged in an array. It should be noted that when interpreting the position of a pixel mentioned below in this disclosure, it may be interpreted as the position of the corresponding light-emitting unit (also referred to as a light-emitting element, such as a light-emitting diode).

In some embodiments, the display panel 100 includes a substrate 210. The substrate 210 may be formed of a polymer material such as glass, polyimide (PI), polycarbonate (PC), polyethersulfone (PES), polyethylene terephthalate (PET), polyethylene naphthalate (PEN), polyarylate (PAR), or fiberglass reinforced plastic (FRP). The substrate 210 may be transparent, translucent, or opaque.

In some embodiments, the display panel 100 may further include a buffer layer 211 disposed on the substrate 110, and the buffer layer may cover the entire upper surface of the substrate 210.

In some embodiments, a driving substrate 200 is disposed on a side of the substrate 210 facing the display surface or touch surface of the display panel 100. The driving substrate 200 may include a stacked structure composed of one or more inorganic materials such as silicon oxide, silicon nitride, and silicon oxynitride.

The driving substrate 200 may include a thin film transistor TFT, a capacitor electrode layer C, and other structures.

As an example, the film layers of the driving substrate 200 may include an active layer 222, a gate insulating layer 223, a gate 224, an intermediate dielectric layer 225, an interlayer dielectric layer 226, a source electrode 227s, a drain electrode 227d, and a passivation layer/first planarization layer 228. Here, the gate insulating layer 223, the intermediate dielectric layer 225, the interlayer dielectric layer 226, and the passivation layer/first planarization layer 228 are insulating layers.

The driving substrate 200 may include a plurality of thin film transistors (TFTs) and pixel circuits composed of the thin film transistors for the light-emitting elements in the light-emitting unit layer.

The embodiments of the present disclosure take a top-gate thin film transistor as an example for structural description. The thin film transistor layers TFT include an active layer 222 located on the substrate 210. The active layer 222 may include a silicon semiconductor or an oxide semiconductor.

In some embodiments, the gate insulating layer 223 is disposed on the active layer 222. The gate insulating layer 223 includes an inorganic layer such as silicon oxide or silicon nitride, and may include a single layer or multiple layers.

In some embodiments, the gate 224 is disposed on the gate insulating layer 223. The intermediate dielectric layer 225 covers the gate 224 and may be disposed on the gate insulating layer 223. The intermediate dielectric layer 225 may include a stacked structure composed of one or more inorganic materials such as silicon oxide, silicon nitride, and silicon oxynitride. In one specific example, the intermediate dielectric layer 225 may include silicon nitride.

The interlayer dielectric layer 226 may be disposed on the intermediate dielectric layer 225 and the capacitor electrode layer C. The interlayer dielectric layer 226 may include a stacked structure composed of one or more inorganic materials such as silicon oxide, silicon nitride, and silicon oxynitride.

It may be understood that the driving substrate 200 includes a driving circuit, and the driving circuit is configured to drive a light-emitting element to emit light 310. As an example, the driving circuit includes a pixel circuit, and the pixel circuit is electrically connected to a light-emitting element 310 and is configured to drive the light-emitting element to emit light.

In some embodiments, the display panel 100 further includes a light-emitting unit layer 300 disposed on one side of the substrate 210. Specifically, the light-emitting unit layer 300 is disposed on a side of the driving substrate 200 away from the substrate 210.

Here, the light-emitting unit layer includes a plurality of pixels SP.

In some embodiments, the light-emitting unit layer 300 includes a plurality of light-emitting elements 310 forming pixels SP.

It may be understood that a pixel SP is formed by a light-emitting element 310, and thus the boundary of a pixel SP in the embodiments of the present disclosure may be defined by the light-emitting element 310.

In some embodiments, the pixel SP/light-emitting element 310 in the present disclosure may be an organic light-emitting diode (OLED), a micro light-emitting diode (micro-LED), or a sub-millimeter light-emitting diode (mini-LED).

In some embodiments, the light-emitting elements in the device disclosed herein may include different types of light-emitting elements at the same time, or may include same types of light-emitting elements. For example, main pixels SP1 and auxiliary pixels SP2 may both be OLEDs, micro-LEDs, or mini-LEDs.

In some embodiments, the light-emitting unit layer 300 includes an anode layer 301, an organic light-emitting material 302, and a cathode layer 303, which are sequentially arranged along a direction away from the substrate 210 and pointing toward the light-emitting surface of the display panel 100.

The light-emitting unit layer 300 further includes a pixel definition layer 340 disposed on the side of the anode layer 301 away from the driving substrate 200. The pixel definition layer 340 may be composed of an organic material such as polyimide (PI), polyamide, benzocyclobutene (BCB), acrylic resin or phenolic resin, or an inorganic material such as SiNx.

In some embodiments, the anode layer 310 includes a plurality of anode patterns corresponding to the pixels SP one by one, and an anode pattern in the anode layer 301 is connected to a source electrode or a drain electrode of the thin film transistor through a via hole. The pixel definition layer 340 is disposed on the side of the anode layer 301 away from the substrate 110 and includes a plurality of openings exposing the anode layer 301, and the pixel definition layer 340 covers the edges of the anode layer 301. The organic light-emitting material 302 is at least partially filled in the opening of the pixel definition layer 340 and is in contact with the anode layer 301.

In some embodiments, the anode layer 301, the organic light-emitting material 302, and the cathode layer 303 defined by each opening of the pixel definition layer 340 form a light-emitting element 310. Different organic light-emitting materials 302 may emit light of different colors to form pixels SP of different colors, and a plurality of pixels SP of different colors display the picture together. It should be noted that the periphery of a pixel SP in the present disclosure refers to the periphery of a light-emitting element 310. That is, when using the periphery of a pixel SP to locate the structures described below, the boundary of the pixel SP is defined by the boundary of the light-emitting element 310, and the periphery of the light-emitting element 310 is the periphery of the pixel SP. In other words, the area where the pixel SP is located may be the area where the opening of the pixel definition layer 340 that accommodates the light-emitting element 310 is located, the boundary of the pixel SP is the boundary of the opening of the pixel definition layer 340, and the periphery of the pixel SP is the periphery of the opening of the pixel definition layer 340.

Furthermore, the pixels SP of the display panel 100 include at least two types of pixels, including main pixels SP1 and auxiliary pixels SP2.

In some embodiments, the auxiliary pixels SP2 are disposed around the main pixels SP1.

In some embodiments, the auxiliary pixels SP2 are disposed between adjacent main pixels SP1.

In some embodiments, the display panel 100 further includes an encapsulation layer 400 disposed on the light-emitting unit layer 300. The encapsulation layer 400 completely covers the light-emitting unit layer 300 to seal the light-emitting unit layer 300. It is to be noted that the “on” mentioned in this embodiment may be understood as being located “on the side away from the substrate”.

In some embodiments, the encapsulation layer 400 is a thin film encapsulation layer, which is disposed on the cathode layer 303 and includes a first inorganic encapsulation layer, a first organic encapsulation layer, and a second inorganic encapsulation layer sequentially arranged along a direction away from the substrate 210. In other embodiments of the present disclosure, the encapsulation layer may include any number of stacked organic materials and inorganic materials as required, but at least one layer of organic material and at least one layer of inorganic material are alternately deposited, and the bottom layer and the top layer are composed of inorganic materials.

In some embodiments, the display panel further includes an auxiliary functional layer 600. The auxiliary functional layer 600 is disposed on the side of the light-emitting unit layer 300 facing the display surface of the display panel 100. That is, the auxiliary functional layer 600 is disposed on the side of the light-emitting unit layer 300 away from the substrate 210.

In some embodiments, the auxiliary function layer 600 is disposed on a side of the encapsulation layer 400 away from the light-emitting unit layer 300.

In some embodiments, the auxiliary functional layer 600 includes first functional components 610, and the first functional components 610 are arranged in a way that correspond to the auxiliary pixels SP2.

It should be noted that the first functional components 610 correspond to the auxiliary pixels SP2, which means that a first functional component 610 is disposed directly above the corresponding auxiliary pixel SP2, and in a direction perpendicular to the plane of the substrate 210 (i.e., the third direction Z), the first functional component 610 at least partially overlaps with the corresponding auxiliary pixel SP2. In some embodiments, the projection of the first functional component 610 in the third direction Z covers the projection of the auxiliary pixel SP2 in the third direction Z.

In some embodiments, when auxiliary pixels SP2 are disposed around a main pixel SP1, the main pixel SP1 is disposed away from a first functional component 610, that is, the first functional component 610 is disposed obliquely above the main pixel SP1.

In some embodiments, in a first state, at least a portion of the first functional component 610 is light-shielding.

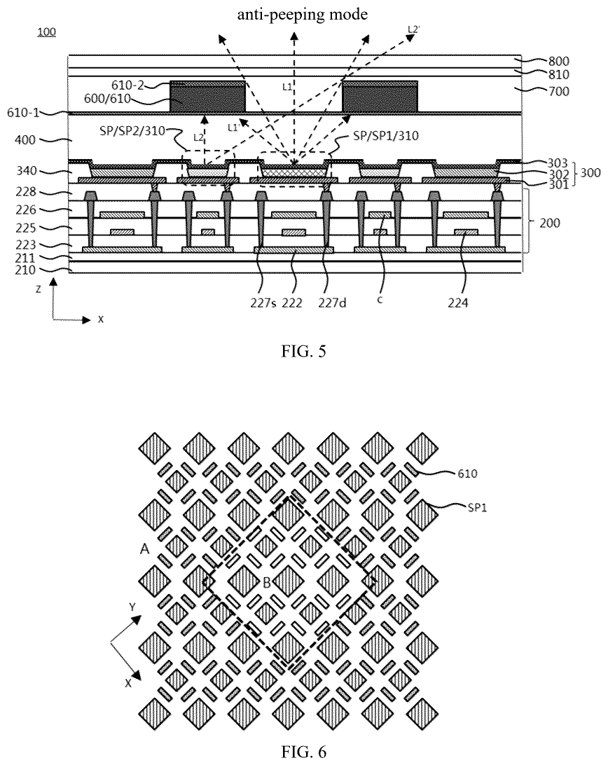

Refer to FIG. 4 and FIG. 5, FIG. 4 is a schematic diagram of light in a second state of the embodiment shown in FIG. 3, and FIG. 5 is a schematic diagram of light in the first state of the embodiment shown in FIG. 3.

In some embodiments, in the first state, since first functional components 610 shield light, main pixels SP1 exposed by the first light shielding parts 610 may be used as the main components for the display panel to perform a light-emitting display. In addition, the auxiliary pixels SP2 arranged around the main pixels SP1 are covered by the first functional components 610, and the light emitted by auxiliary pixels SP2 will not be seen at a normal viewing angle of the display panel. The normal viewing angle may be a center normal viewing angle or a viewing angle substantially directed toward the display panel.

In addition, in the first state, a first functional component 610 is transformed into the light-shielding state and its surrounding area may form an anti-peeping mode. Specifically, at a normal viewing angle and a small viewing angle, the small-angle light L1 emitted by a main pixel SP1 will not be blocked by the first functional component 610 in its oblique direction, and thus may be viewed. However, the small-angle light L2 emitted by the auxiliary pixel SP2 is blocked by the first functional component 610 and cannot be viewed. At a large viewing angle, when the large-angle light L1′ emitted by the main pixel SP1 is blocked by the first functional component 610 in its oblique direction and cannot be viewed, the large-angle light L2′ emitted by the auxiliary pixel SP2 may be viewed from the oblique direction through the opening portion of the first functional component(s) 610. Accordingly, a viewer at a large viewing angle may only see the interfering light emitted by the auxiliary pixels SP2. Therefore, the display panel provided in the embodiments of the present disclosure may achieve an anti-peeping effect, thereby well protecting the privacy of the user.

In some embodiments, the display panel also includes a second state. In the first state, the electrochromic material is in a light-shielding state. In the second state, the electrochromic material is in a transparent state.

In some embodiments, the first state is an anti-peeping mode, and the second state is a normal mode.

In the second state, the electrochromic material is transparent, so the small-angle light L2 emitted by an auxiliary pixel SP2 will not be blocked by the corresponding first functional component 610 and may also be viewed. The large-angle light L1′ emitted by a main pixel SP1 will not be blocked by the corresponding first functional component(s) 610 in its oblique direction, and may also be viewed. Therefore, the display at a normal viewing angle and the display at a large viewing angle are contributed by both the auxiliary pixels and the main pixels.

With such a design, the display panel may have at least two viewing angles. Moreover, since the display at the normal viewing angle and the display at the large viewing angle both involve the auxiliary pixels and the main pixels, the uniformity of the display effect at each viewing angle in the second state may be improved.

It should be noted that the first state and the second state mentioned in this disclosure do not only mean that the entire display panel is in the anti-peeping mode, but may be a partial anti-peeping state. In other words, the first state and the second state may be understood as the light-transmitting state of the electrochromic material. It controls whether the corresponding display panel area is in the normal mode or the anti-peeping mode. This will be explained in detail below.

In some embodiments, it is possible to further control whether to light an auxiliary pixel to match the state of the first functional layer, thereby further improving the anti-peeping effect. In some embodiments, in the first state, the main pixels SP1 emit light, the auxiliary pixels SP2 do not emit light, and the electrochromic luminescent material is in a light-shielding state. In the second state, the main pixels SP1 emit light, the auxiliary pixels SP2 emit light, and the electrochromic luminescent material is in a transparent state. In another first state, the main pixels SP1 emit light, the auxiliary pixels SP2 emit light, and the electrochromic luminescent material is in a light-shielding state.

In some embodiments, a first functional component 610 includes an electrochromic material.

Specifically, a first functional component 610 includes a control electrode layer 610 disposed on at least one side of the electrochromic material. For example, the control electrode layer 610 includes a first control electrode layer 610-1 and a second control electrode layer 610-2 disposed on two opposite sides of the electrochromic material in a direction perpendicular to the display panel 100 (i.e., in the third direction Z). It may be understood that in the normal mode, the control electrode layer 610 is not applied with a voltage, and the electrochromic material is in a transparent state. When in the anti-peeping mode, at least part of the control electrode layer 610 is applied with a voltage, and the transmittance of the electrochromic material corresponding to the control electrode layer 610 applied with a voltage changes and turns into a light-shielding state. The light-shielding state includes a black state or a gray state.

In some embodiments, the electrochromic material includes an ion storage layer, an electrolyte layer, and a color-changing material layer. The electrochromic material includes tungsten oxide (WO3), which may be switched between a transparent state and a light-shielding state.

In some embodiments, the display panel 100 further includes a cover plate 800 disposed on the auxiliary function layer 600. The cover plate 800 may be a glass material or a flexible protective film layer. In some embodiments, the display panel 100 further includes a polarizing layer 810 disposed under the cover plate 800, and the polarizing layer 810 may include a circular polarizer.

In some embodiments, the display panel 100 also includes a second planarization layer 700 disposed on the auxiliary function layer 600. Specifically, the second planarization layer 700 is disposed between the auxiliary function layer 600 and the cover plate 800, or between the auxiliary function layer 600 and the polarizing layer 810. The second planarization layer 700 may cover the auxiliary function layer 600. In some embodiments, the second planarization layer 700 is an organic film layer having a certain thickness. Since the first functional components in the present disclosure need to be specifically set on different auxiliary pixels, in order to achieve the partitioned or angled control described below, some of the first functional components are spaced apart, and thus the first functional components have a target patterned design. The second planarization layer 700 provided in the disclosure may provide a uniform and flat bearing surface for disposing the polarizing layer 810 or the cover plate 800.

Continue to refer to FIG. 2 to FIG. 3, in some embodiments, at least two main pixels of different colors are periodically and alternately arranged in the first direction X and/or the second direction Y to form a main pixel array. The auxiliary pixels are disposed between adjacent main pixels in the first direction X or the second direction Y, where the first direction X and the second direction Y intersect.

Through such a design, two adjacent main pixels may share the interference light of an auxiliary pixel for anti-peeping function. This may improve the utilization rate of auxiliary pixels. On one hand, it improves the light utilization rate of auxiliary pixels and reduces power consumption. On the other hand, it optimizes the arrangement of main pixels and auxiliary pixels, reduces the proportion of auxiliary pixels, and saves space on the display panel.

It should be noted that the first direction X and the second direction Y are both parallel to the plane where the display panel is located. In some embodiments, the first direction X and the second direction Y are perpendicular.

In some embodiments, as shown in FIG. 2 and FIG. 3, the display panel 100 includes main pixels SP1 of three colors. In the first direction X, the main pixels of the first color and the second color are arranged alternately, or the main pixels of the first color and the third color are arranged alternately. For example, the main pixels SP1 of the first color are adjacent to the main pixels SP1 of the second color on two opposite sides in the first direction X, and adjacent to the main pixels SP1 of the third color on two opposite sides in the second direction Y.

Specifically, the display panel 100 includes main pixels SP1 of three colors: red, green, and blue. In the first direction X, the blue main pixels and the green main pixels are arranged alternately, or the red main pixels and the green main pixels are arranged alternately. The red main pixels are arranged adjacent to the green main pixels on two opposite sides in the first direction X, and are arranged adjacent to the blue main pixels on the two opposite sides in the second direction Y.

In some embodiments of the present disclosure, the auxiliary pixels SP2 are white light pixels. With such a design, since the interference degree of white light pixels on pixels of other colors is uniform, the interference degree on the main pixels of various colors may be made similar under a large viewing angle, thereby improving the uniformity of display and anti-peeping.

In some embodiments, an auxiliary pixel SP2 is set between two adjacent main pixels SP1. That is, two adjacent main pixels SP1 share an auxiliary pixel SP2 between them. In other words, main pixels of different colors share a white light auxiliary pixel. Because the light emitted by the white light auxiliary pixel includes ingredients of the same color as the light emitted by pixels of the other three colors, the interference effect is more uniform in the first state. In the second state, the auxiliary pixels may better cooperate with the main pixels to emit light without excessively disrupting the rendering effect between main pixels of different colors. In particular, for the main pixel arrangement of the above-described embodiments, by setting an auxiliary pixel that emits white light, the rendering effect of the main pixels may be guaranteed when the auxiliary pixel participates in a conventional display, thereby improving the PPI of the display panel, with the anti-peeping function, to a certain extent, and at the same time improving the anti-peeping effect.

In some embodiments, a green main pixel has the smallest corresponding area, that is, the area of a blue main pixel is larger than that of a green main pixel and the area of a red main pixel is larger than that of a green main pixel.

In some embodiments, the auxiliary pixels may directly use light-emitting elements that emit white light.

In other embodiments, a blue light-emitting element may be superimposed with a color conversion layer to form an auxiliary pixel, so that the auxiliary pixel may emit white light. For example, an auxiliary pixel includes a blue light-emitting element superimposed with a quantum dot film, or a blue light-emitting element superimposed with a phosphor layer.

In some embodiments, an auxiliary pixel emitting white light may be a pixel formed by stacking or combining light-emitting elements of three colors: red, green, and blue.

In one example, light-emitting elements or light-emitting materials of three colors are stacked in the third direction Z, i.e., stacked RGB light-emitting elements of three colors.

In another example, an auxiliary pixel includes adjacently arranged RGB light-emitting elements of three colors, that is, a combined RGB three-color light-emitting element.

In some embodiments, an auxiliary pixel is a white light pixel synthesized by adjacently arranged RGB microLED light-emitting elements. In this way, the microLEDs of three colors may be disposed to the position of the auxiliary pixel by direct transfer, which may not only realize the auxiliary pixel to emit white light, but also reduce the space occupied by the three-color pixel. In some embodiments, the microLEDs of three colors may be set on the electrode of a same auxiliary pixel by direct transfer.

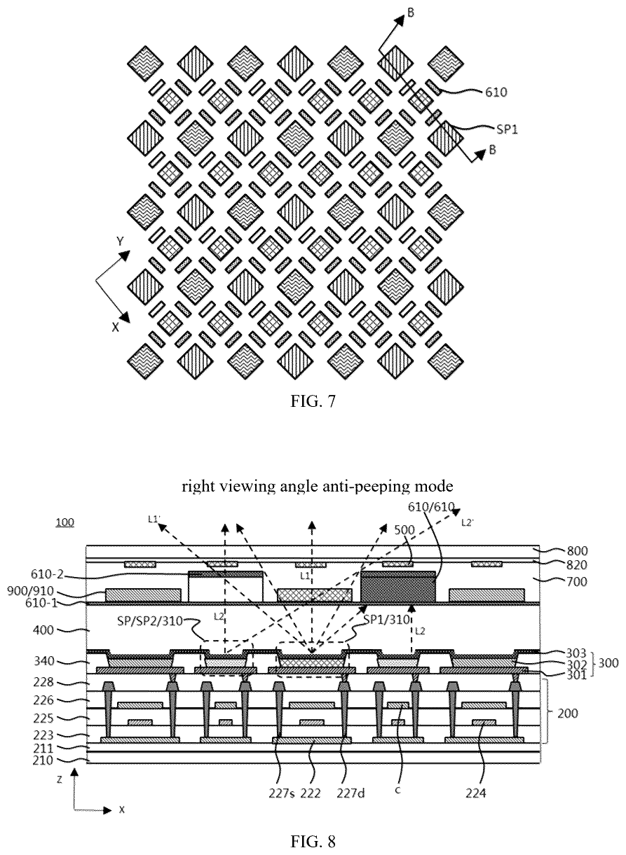

FIG. 6 and FIG. 7 are respectively two other partial enlarged top views of the display panel provided in the embodiments of the present disclosure.

In some embodiments, in the first state, at least a portion of the first functional component 610 is transparent. Such a design may enable the display panel or a local display area to be protected from peeping at a specific viewing angle.

In some embodiments, as shown in FIG. 6, when the display area of the display panel is partially protected from peeping, it means that at least part of the display area is in the anti-peeping mode, and at least part of the display area is in the normal mode. Here, the area that is to be in the anti-peeping mode is referred to as area A, and the area that is to be in the normal mode is referred to as area B.

In area A, a voltage is applied between the first control electrode layer 610-1 and the second control electrode layer 610-2 on both sides of the electrochromic material of all the first functional components 610, or the voltage difference between the first control electrode layer 610-1 and the second control electrode layer 610-2 is greater than 0 V, so that the first functional components are in the first state. Accordingly, the area where the first functional components are located (i.e., area A) is converted to the anti-peeping mode in the first state. For area B, no voltage is applied between the first control electrode layer 610-1 and the second control electrode layer 610-2 on both sides of the electrochromic material of all the first functional components 610, or the voltage difference between the first control electrode layer 610-1 and the second control electrode layer 610-2 is 0 V, so that the first functional components are in that area in the second state. Accordingly, the area where the first functional components are located in the second state (i.e., area B) is in the normal mode for display. In one example, area A is a display area for password input or display, and area B is the non-privacy information display area.

Under certain application scenarios, since a viewer cannot look directly at the display area, it is hoped that a display area has a specific anti-peeping direction. In one example, in a car display, the central display screen is neither facing the driver's seat nor the passenger seat. At this moment, in order to prevent the display image from affecting the driver, or the displayed content is confidential information, it is hoped that the display image may only be seen by one of them.

Refer to FIG. 7 and FIG. 8, FIG. 8 is a partial cross-sectional view along the BB direction in FIG. 7, where the cross-section is perpendicular to the plane where the display panel is located. In some embodiments, for an area where a specific angle of privacy protection is required, the first functional components 610, corresponding to the main pixels, in a direction where privacy protection is required are in a first state (i.e., the electrochromic material in the viewing angle direction is in a light-shielding state). The first functional components 610 in a direction where privacy protection is not required are in a second state (i.e., the electrochromic material in the viewing angle direction is in a light-transmitting state or transparent state).

In some embodiments, auxiliary pixels SP2 are arranged along at least two directions around at least one main pixel SP1. In this way, the display panel may achieve selective privacy protection in at least two viewing directions.

It is to be noted that, the present disclosure is not limited to the viewing angle protection in two viewing directions. That is, at least one main pixel SP1 may include auxiliary pixel SP2 configured in three directions, four directions, or N directions. The direction mentioned here refers to the orientation of the auxiliary pixels relative to a main pixel when disposing the auxiliary pixels. In addition, the direction disclosed herein is parallel to the plane where the display panel is located.

In some embodiments, an auxiliary pixel SP2 is disposed between two adjacent main pixels SP1, that is, the two adjacent main pixels SP1 share the auxiliary pixel SP2 therebetween.

In this case, one of the two main pixels that share the auxiliary pixel is the first main pixel. When an anti-peeping display is required at a specific angle, the state of a first functional component is selected based on the first main pixel. That is, when an anti-peeping display is required in the first direction and a normal display is required in the second direction, the first functional component corresponding to an auxiliary pixel adjacent to the first main pixel along the first direction is in the first state, and the first functional component corresponding to an auxiliary pixel adjacent to the first main pixel along the second direction is in the second state.

In some embodiments, in the anti-peeping mode in a specific direction, a first functional component on the side of the first main pixel that needs to be anti-peeping is in a first state, that is, a light-shielding state.

In some embodiments, in the 360-degree anti-peeping mode, the first functional component on each side of the first main pixel that needs to be anti-peeping is in a first state, that is, a light-shielding state.

In some embodiments, the display panel includes main pixels of three colors: red, green, and blue, where a green main pixel has the smallest corresponding area. In the first direction X, the blue main pixels and the green main pixels are arranged alternately, or the red main pixels and the green main pixels are arranged alternately. In one example, the red main pixels are arranged adjacent to the green main pixels on two opposite sides in the first direction X, and the blue main pixels are arranged adjacent to the green main pixels on two opposite sides in the second direction Y.

Furthermore, the green main pixels are the first main pixels. For example, as shown in FIG. 8, taking a green main pixel as the base point, when a right-angle peeping protection is required, the first functional component corresponding to the auxiliary pixel on the right side of the green main pixel is light-shielding, and the first functional component corresponding to the auxiliary pixel on the left side of the green main pixel is light-transmissive. In this way, the green main pixel may emit light toward the left side at a large angle of view, while the light toward the right side at a large angle of view will be blocked by the first functional component on the right. The light emitted from the auxiliary pixel on the right side at a normal angle of view will also be blocked by the first functional component. The right angle of view will also be affected by the large-angle interference light emitted by the auxiliary pixel on the left side of the green main pixel, such as the light L2′.

In some embodiments, a green main pixel as the first main pixel has the smallest corresponding area. That is, the area of a blue main pixel is larger than that of a green main pixel, and the area of a red main pixel is larger than that of a green main pixel. This may further improve the anti-peeping effect.

Continue to refer to the embodiments corresponding to any of FIG. 2 to FIG. 3, FIG. 6 or FIG. 7 to FIG. 8. In some embodiments, a plurality of auxiliary pixels SP2 are arranged at intervals around a main pixel SP1.

The applicant has found that since auxiliary pixels also require an evaporation mask for evaporation, by designing auxiliary pixels surrounding a main pixel as a multiple interval configuration, a non-closed annular evaporation mask may be used, which reduces the process difficulty. In addition, the uniformity of anti-peeping at 360 degrees is also accounted for.

In some embodiments, at least two auxiliary pixels SP2 are disposed on a same side of a same main pixel SP1 and are arranged along an extension direction of one edge of the same main pixel SP1. In this way, the anti-peeping effect may be made more uniform while taking into account the process difficulty.

Further, with reference to the above drawings and FIG. 9, FIG. 9 is a partial enlarged top view of a display panel provided by the present disclosure.

In some embodiments, a plurality of auxiliary pixels SP2 are arranged around a main pixel SP1 at intervals. The plurality of auxiliary pixels SP2 corresponding to a same main pixel SP1 form an auxiliary pixel group, and the auxiliary pixels SP2 in a same auxiliary pixel group share a driving circuit.

Furthermore, a plurality of auxiliary pixels SP2 corresponding to a same main pixel SP1 form an auxiliary pixel group, and the auxiliary pixels SP2 in the auxiliary pixel group correspond to a same first functional component 610.

Through such a design, the difficulty of patterning may be reduced, the process may be simplified, the display panel space may be better utilized, and the cost may be reduced, and the anti-peeping and display effects may be accounted for at the same time.

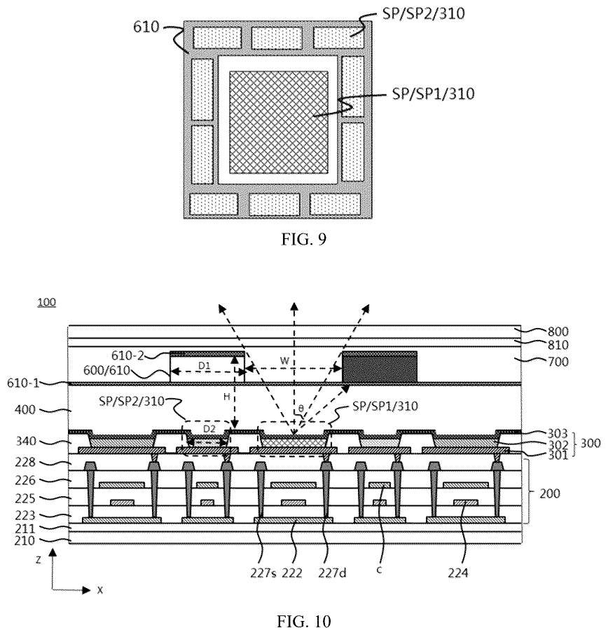

FIG. 10 is a partial cross-sectional view along the AA direction in FIG. 2, or a partial cross-sectional view along the BB direction in FIG. 7, or a cross-sectional view of some other embodiments of the present disclosure, where the cross-section is perpendicular to the plane where the display panel is located. The cross-sectional views of the following embodiments of the present disclosure may all be understood by referring to the above descriptions, and will not be repeated below.

In some embodiments, the size of a first functional component 610 is larger than the size of an auxiliary pixel SP2.

In some embodiments, the width D1 of a functional component 610 is greater than the width D2 of the corresponding auxiliary pixel SP2. In some embodiments, the width direction is the direction of a connection line connecting the main pixels on two opposite sides of an auxiliary pixel, for example, as shown in FIG. 10.

In some embodiments, the projection area of a first functional component 610 in the third direction Z is greater than the projection area of the corresponding auxiliary pixel SP2 in the third direction Z. In some embodiments, the projection of the first functional component 610 in the third direction Z covers the projection of the corresponding auxiliary pixel SP2 in the third direction Z.

It should be noted that a viewing angle of the disclosure refers to an angle between a viewer's position and the center normal direction of the display panel (i.e., the normal line passing through the center of the display panel and perpendicular to the surface where the display panel is located). When the angle is substantially 0°, it may be understood as a normal viewing angle. When the angle is less than the minimum anti-peeping angle, it may be understood as a small viewing angle. When the angle is equal to or greater than the minimum anti-peeping angle, it may be understood as a large viewing angle. The minimum anti-peeping angle is determined according to demand.

In some embodiments, a first functional component 610 and the corresponding auxiliary pixel SP2 are directly opposite to each other in the third direction Z. That is, in a cross-section parallel to the third direction Z and parallel to the first direction X or the second direction Y, the center of the first functional component is directly opposite to the center of the auxiliary pixel, to avoid any inclination between the two, thereby avoiding affecting the display performance in the large viewing angle display mode.

In some embodiments, the shape of a first functional component 610 is similar to the shape of the corresponding auxiliary pixel SP2. That is, in a pair of the first functional component and the auxiliary pixel, the first functional component is a proportionally enlarged figure of the auxiliary pixel. The shape mentioned here may be understood as the shape of the orthographic projection on the plane where the display panel is located along the third direction Z. In this way, the amount of interference light emitted by the auxiliary pixel in all directions may be ensured to be uniform, thereby improving the uniformity of anti-peeping effect.

Continue to refer to FIG. 10, the display panel 100 satisfies the formula: W=2×H×tan θ, where W is the distance between adjacent first functional components, H is the distance from the light-emitting unit layer to the top of the first functional component(s), and θ is the anti-peeping angle.

In some embodiments, W is a distance parallel to the first direction X, i.e., a distance in a direction of a connection line connecting main pixels on both sides of an auxiliary pixel.

In some embodiments, the anti-peeping angle may be a minimum anti-peeping angle, and the minimum anti-peeping angle may be determined according to demand.

In some embodiments, H is the distance from the top of the pixel definition layer 340 to the top of the first functional component(s). The top of a structure disclosed here is the surface of the structure facing away from the substrate. Through such a design, the anti-peeping effect may be further improved.

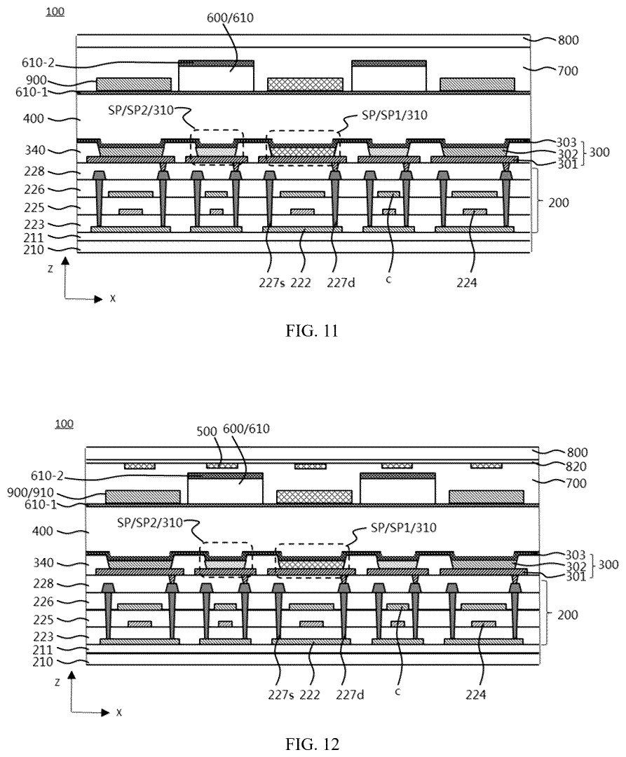

FIG. 11 to FIG. 13 are cross-sectional views of a display panel provided by the present disclosure.

In some embodiments, the display panel 100 further includes a color resist layer 900, and the color resist layer 900 is disposed on a side of the light-emitting unit layer 300 away from the substrate 210.

With such a design, at least one circular polarizer may be saved, the overall power consumption of the display panel may be reduced, the transmittance of the display panel may be increased, and the display effect of the display panel may be improved. In some embodiments, the cover plate 800 is directly disposed on the second planarization layer 700. Through such a design, the anti-peeping effect and display effect may be further optimized.

In some embodiments, as shown in FIG. 11 to FIG. 13, the color resist layer 900 includes a main color resist 910, and the main color resist 910 corresponds to a main pixel SP1.

It should be noted that a main color resist 910 corresponding to a main pixel SP1 means that the main color resist 910 is disposed directly above the main pixel SP1. In other words, the projection of the main color resist 910 in the third direction Z covers the projection of the main pixel SP1 in the third direction Z.

Furthermore, in view of an auxiliary pixel SP2 being a white light pixel, the white light emitted by the auxiliary pixel may still interfere with the display content at a large viewing angle. In addition, due to the filtering of the main color resist, the wide-viewing angle light emitted by the auxiliary pixel may be consistent with the color of the corresponding main pixel that needs to be interfered with, thereby better forming color-contrast interference. Especially, in a case where main pixels of different colors share an auxiliary pixel, the auxiliary pixel of one color (i.e., the auxiliary pixel is a white light pixel) may specifically emit a wide-viewing angle of light with colors corresponding to the main pixels of different colors on different sides of the auxiliary pixel, thereby more specifically interfering with pixels of different colors at a large viewing angle. This further improves the anti-peeping effect.

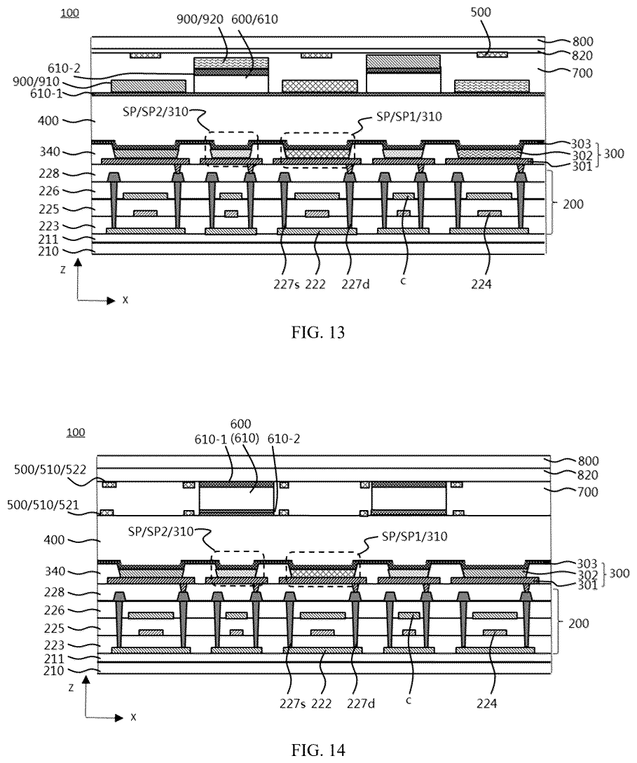

In some embodiments, as shown in FIG. 13, the color resist layer 900 further includes an auxiliary color resist 920, and the auxiliary color resist 920 corresponds to an auxiliary pixel SP2.

It should be noted that the auxiliary color resist 920 corresponding to the auxiliary pixel SP2 means that the auxiliary color resist 920 is disposed directly above the auxiliary pixel SP2. That is, the projection of the auxiliary color resist 920 in the third direction Z covers the projection of the auxiliary pixel SP2 in the third direction Z.

Through this color design, in a normal display, the auxiliary pixels may also be displayed as pixels with specific colors to increase the display PPI. At the same time, the auxiliary pixels may also provide interference light of other colors in anti-peeping mode.

In some embodiments, the color of an auxiliary color resist 920 is different from the color of an adjacent main pixel SP1. Through this configuration, color crosstalk in the normal mode may be avoided. In some embodiments, the auxiliary color resist 920 may also be configured to further filter the large-angle light emission of a main pixel SP1 in the anti-peeping mode to improve the anti-peeping effect. In addition, in the normal mode, auxiliary pixels may also be rendered with the main pixels to improve the display effect.

In some embodiments, the pixel arrangement rule is: along the first direction X, the main pixels SP1 of the three colors of RGB are arranged alternately, that is, the arrangement order is. . . -RGBRGB—. . . ; along the second direction Y, the main pixels SP1 of the same color are arranged adjacent to each other, that is, the main pixels SP1 of the same row in the second direction Y are the main pixels SP1 of the same color. The auxiliary pixels SP2 are disposed between adjacent main pixels SP1 of different colors in the first direction X. In this way, the auxiliary pixels and the main pixels together still form a repetitive color arrangement of RGB in the first direction X.

Through the embodiment disclosed herein, the pixel arrangement is combined with the auxiliary color resists 920 correspondingly disposed on the auxiliary pixels SP2. In the anti-peeping mode, the auxiliary color resists 920 are configured to further filter the wide-angle light emission of the main pixels SP1, which makes the display panel 100 to maintain a better rendering effect while improving the PPI in the normal mode, and also have an anti-peeping function, thereby further improving the anti-peeping and display effects.

In some embodiments, an auxiliary color resist 920 is disposed on a side of a first functional component 610 facing away from the substrate 210, and has the same outline and area as the first functional component 610.

In some embodiments, au auxiliary color resist 920 and the corresponding first functional component 610 are disposed adjacent to each other in the third direction Z, and their projections in the third direction Z overlap.

In some embodiments, an auxiliary color resist 920 may be disposed between the corresponding first functional component 610 and light-emitting element 310.

Refer to FIG. 12 to FIG. 14, FIG. 14 is a cross-sectional view of another display panel provided by the present disclosure.

The similarities between the illustrated embodiment and the above embodiments will not be repeated. The difference lies in that the display panel 100 further includes a touch function layer 500, and the touch function layer 500 is disposed on a side of the light-emitting unit layer 300 away from the substrate 210.

In some embodiments, the touch function layer 500 includes at least one touch electrode layer, and the at least one touch electrode layer is disposed on a side of the first function part 610 away from the substrate 210.

With such a design, at least part of the touch structure may be close to the light-emitting surface of the display panel (i.e., the touch surface), so that both anti-peeping and touch sensitivity may be accounted for. In addition, at least part of a touch electrode may be close to the finger, thereby improving the touch effect.

In some embodiments, the touch electrode layer may be made of transparent ITO material. Furthermore, at least part of a touch electrode overlaps with a pixel SP. With such a design, on one hand, an auxiliary function layer may be added to increase the touch area to improve the touch performance. On the other hand, the touch function layer may be prevented from blocking the main pixels and the auxiliary pixels, thereby ensuring the touch effect while also taking into account the display performance.

As shown in FIG. 14, in some embodiments, the touch function layer 500 is disposed on the encapsulation layer 400 of the display panel 100, that is, the touch function layer 500 is disposed on a side of the encapsulation layer 400 away from the light-emitting element 310.

In some embodiments, the touch function layer 500 includes at least one touch electrode layer 510, and a first functional component 600 also includes a control electrode layer 610 disposed on at least one side of the electrochromic material, and the at least one touch electrode layer 510 is in the same layer as the control electrode layer 610. In other words, the control electrode layer 610 is in the same layer and made of the same material as one or more film layers in the touch function layer 500.

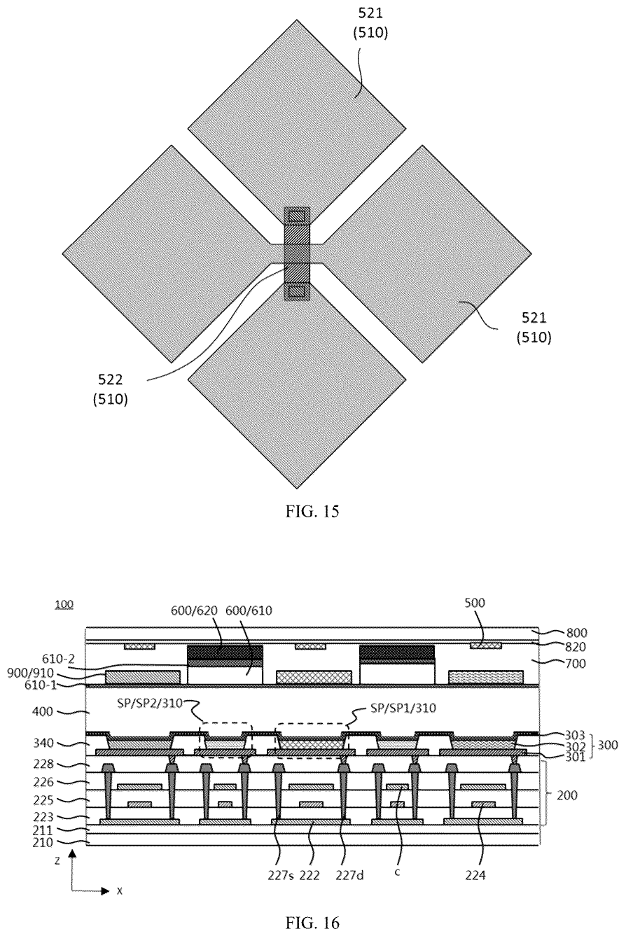

Refer to FIG. 14 and FIG. 15, FIG. 15 is a top view of a touch electrode layer in a touch function layer in a display panel in accordance with an embodiment of the present disclosure. The similarities between the illustrated embodiment and the above embodiments are not repeated. The difference is that the touch electrode layer 510 includes a first touch conductive layer 521 and a second touch conductive layer 522.

In some embodiments, the control electrode layer 610 includes a first control electrode layer 610-1 and a second control electrode layer 610-2 disposed on both sides of the electrochromic material in a direction perpendicular to the display panel (i.e., in a third direction Z). The first control electrode layer 610-1 is in the same layer and made of the same material as the first touch conductive layer 521, and/or the second control electrode layer 610-2 is in the same layer and made of the same material as the second touch conductive layer 522.

Through such a design, the film layers may be reduced, so that the display panel may have more functions and the thickness of the display panel may be reduced.

In some embodiments, the display panel 100 further includes a covering layer 820 disposed under the cover plate 800. In some embodiments, the covering layer 820 may be formed between the auxiliary function layer 600 and the cover plate 800. In some embodiments, the covering layer 820 may be formed between the touch electrode layer 510 of the touch function layer 500 and the cover plate 800, and at least part of the electrode layer in the touch electrode layer 510 may be adjacent to the covering layer 820, or the covering layer 820 may be formed as a carrier film layer and then bonded to the display panel main body.

It should be noted that, in some embodiments, the first touch conductive layer 521 and the second touch conductive layer 522 may be an electrode layer and a bridge layer, respectively. In the disclosed embodiment, a film layer where the electrode layer is located is the first touch conductive layer 521, and a film layer where the bridge layer is located is the second touch conductive layer 522. In some embodiments of the present disclosure, a film layer where the electrode layer is located is the second touch conductive layer 522, and a film layer where the bridge layer is located is the first touch conductive layer 521.

In addition, in other technical solutions corresponding to the disclosed embodiments, the touch function layer 500 may include only one touch electrode layer. In some embodiments, when the touch function layer 500 includes only one touch electrode layer, the touch electrodes included therein are in self-capacitance mode.

In some embodiments, the touch electrode layer 510 is a metal grid structure. In some embodiments, the metal grid includes metal lines (or grid lines) that cross each other.

In some embodiments, the metal wires are disposed in the interval between the pixels SP, and the metal wires are disposed around the pixels or the light-emitting elements 310, and do not block the light emitted from the light-emitting elements at a normal viewing angle, but will intercept or block the light emitted at a large viewing angle.

Through the embodiments of the present disclosure, the touch electrodes are configured at the same layer as the control electrodes in the first functional components. On one hand, the touch electrodes may be made according to the process of the control electrodes in the first functional components, saving film layers and reducing costs. On the other hand, since the film layer of the touch electrodes is raised to the level where the first functional components are located, the touch electrodes made of metal may be reused to further improve the anti-peeping effect.

In particular, when the touch electrodes made of metal material are configured in the same layer as the first control electrode layer, in the anti-peeping mode, the wide-angle light reflected by the touch electrodes made of metal material may be blocked by the first functional components, so as to avoid the wide-angle light reflected by the metal in the anti-peeping mode being particularly obvious, which further improves the anti-peeping effect, and reduces the difference in the reflected light of the touch metal in the anti-peeping mode and the non-anti-peeping mode.

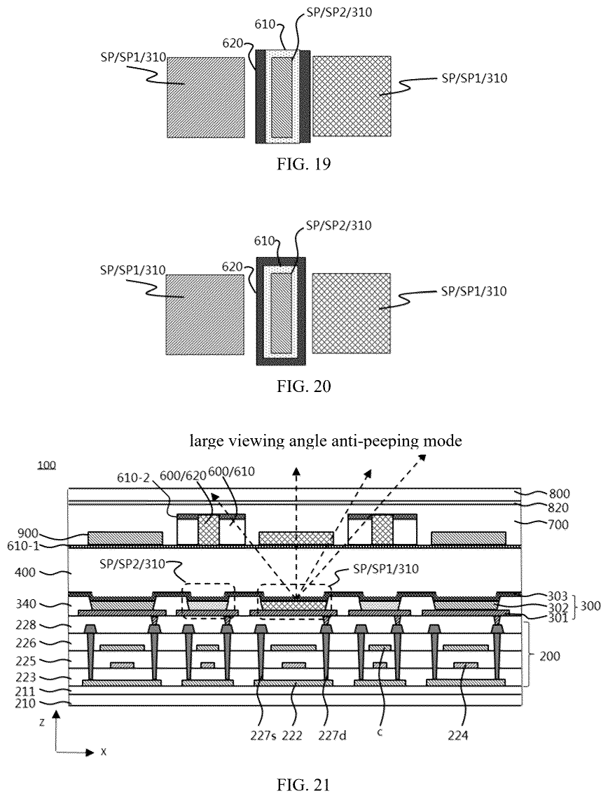

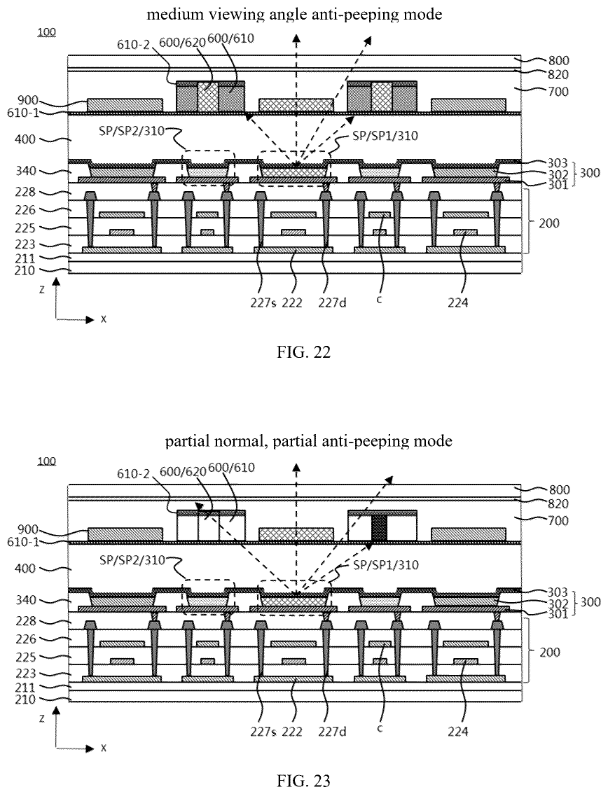

As shown in FIGS. 16 to 22, FIGS. 16 to 18 and FIGS. 21 to 22 are cross-sectional views of a display panel provided by the present disclosure. FIGS. 21 and 22 also include light schematic diagrams of the display panel in two states. FIGS. 19 and 20 are partial enlarged top views of a display panel provided by the present disclosure.

In some embodiments, the auxiliary functional layer 600 further includes a second functional component 620. A second functional component 620 is a light-shielding layer, and the second functional component 620 exposes an auxiliary pixel SP2.

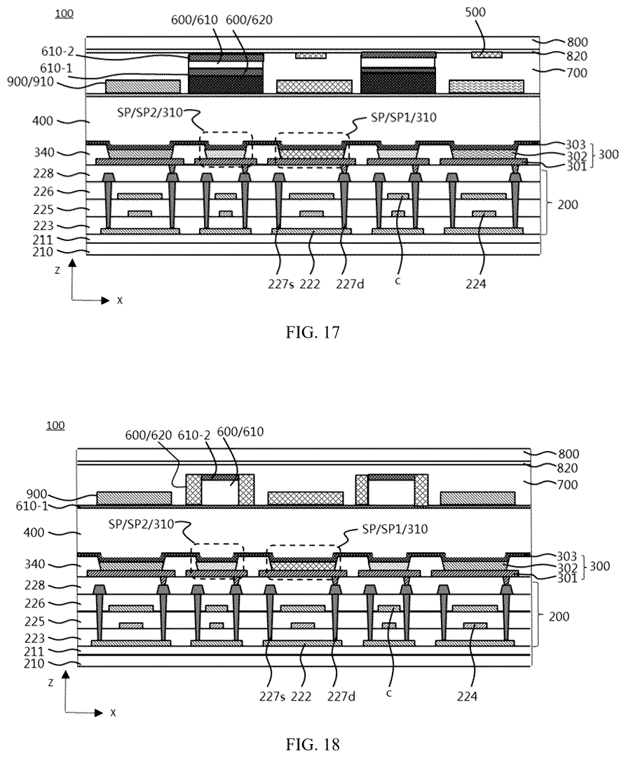

In some embodiments, as shown in FIGS. 16 and 17, a second functional component 620 overlaps with a first functional component 610.

In some embodiments, a second functional component 620 and a first functional component 610 are disposed adjacent to each other in the third direction Z, and their projections in the third direction Z overlap.

In some embodiments, as shown in FIG. 16, a second functional component 620 is disposed on a side of a first functional component 610 facing away from the substrate 210, and has the same contour and area as the first functional component 610.

In some embodiments, as shown in FIG. 17, a second functional component 620 is disposed on the side of a first functional component 610 facing the substrate 210 and has the same contour and area as the first functional component 610. In this way, the display panel may have an anti-peeping function and the magnitude of the anti-peeping viewing angle may be adjusted through the first functional component.

In some embodiments, a second functional component 620 is disposed on at least one side wall of a first functional component 610. That is, the second functional component 620 and the first functional component 610 are adjacently disposed in a direction parallel to the plane where the display panel 100 is located.

In some embodiments, referring to FIGS. 18 to 20, second functional components 620 are disposed on at least two sides of a first functional component 610, and the first functional component 610 directly faces an auxiliary pixel SP2.

In some embodiments, two second functional components 620 are symmetrically arranged with respect to a first functional component 610, or a second functional component 620 is arranged around the first functional component 610.

Specifically, as shown in FIG. 19, the second functional components 620 are disposed on both sides of the first functional component 610 in the width direction, or disposed on both sides of the first functional component 610 along a direction where the main pixels SP1 connect, or disposed between the first functional component 610 and a main pixel SP1. The positional relationship description here may be understood as the positional relationship between the projections of the main pixels SP1 and the first functional component 610 and the second functional components 620 on the plane where the display panel is located.

In some embodiments, in combination with the top view, a second functional component 620 is disposed at least on one side of the length edge of a first functional component 610 corresponding to the auxiliary pixel SP2.

Through the above embodiments, on one hand, the anti-peeping effect of the second functional components may be further improved, and on the other hand, sufficient space may be provided for the arrangement of the second functional components.

In some embodiments, as shown in FIG. 20, a second functional component 620 is disposed around a first functional component 610, which is equivalent to the first functional component 610 being disposed in an opening formed by the second functional component 620. This not only allows the second functional component to further improve the anti-peeping effect, but also improves the anti-peeping uniformity in all viewing directions.

Refer to FIGS. 21 and 22, in some embodiments, a second functional component 620 is disposed in at least one opening of a first functional component 610. That is, the first functional component 610 is arranged around the second functional component 620. Through such a design, the display panel may have different degrees of anti-peeping viewing angles. Specifically, as shown in FIG. 21, the first functional component 610 is in the second state, that is, the light-transmitting state. At this moment, the medium viewing angle light, between the large viewing angle and the normal viewing angle, emitted by the main pixel may pass through the first functional component, and the light at the large viewing angle will be blocked by the second functional component 620, so a large viewing angle anti-peeping mode may be presented. Refer to FIG. 22, the first functional component 610 is in the first state, that is, the light-shielding state. At this moment, the light emitted by the main pixel in the large viewing angle and the medium viewing angle will both be blocked by the first functional component 610 and the second functional component 620, so a medium viewing angle anti-peeping mode may be presented.

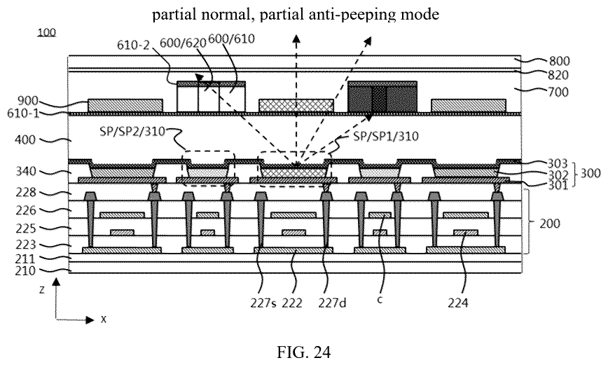

FIGS. 23 and 24 are cross-sectional views of a display panel provided by the present disclosure, respectively, which also include light schematic diagrams of the display panel disclosed herein. In some embodiments, a second functional component 620 may also be an electrochromic material. Here, the similarities between the second functional component 620 and the first functional component 610 are not repeated. Differently, when a normal mode display is required, the second functional component 620 and the first functional component 610 disposed between the main pixels may both present a second state, that is, a light-transmitting state. When an anti-peeping mode display is required, one or more of the second functional component 620 and the first functional component 610 disposed in the same main pixel interval may be selected as needed to be a first state, that is, a light-shielding state. In this way, not only the anti-peeping and normal modes may be achieved, but also the magnitude of the anti-peeping viewing angle may be selected. According to the combination of different states of the second functional component 620 and the first functional component 610, different anti-peeping angles may be achieved.

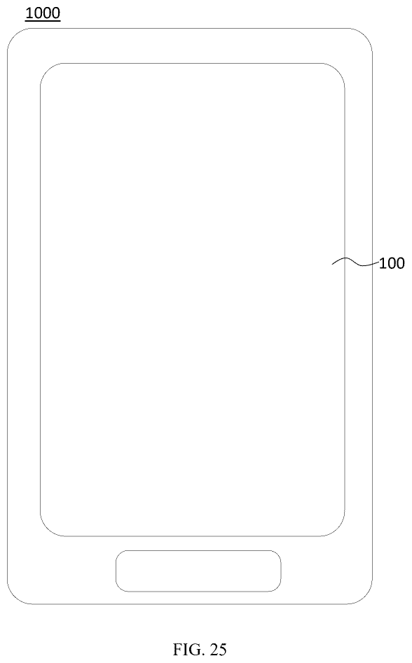

The present disclosure also provides a display device, including a display panel provided by the present disclosure. FIG. 25 is a schematic diagram of the structure of a display device in accordance with an embodiment of the present disclosure. The display device 1000 includes a display panel 100 provided by any of the above embodiments of the present disclosure. The illustrated embodiment of FIG. 25 only takes a mobile phone as an example to illustrate the display device 1000. It may be understood that the display device provided by the embodiments of the present disclosure may be a computer, a television, a car display device or other display devices with a display function, which is not limited in the present disclosure. The display device provided by the embodiments of the present disclosure has the beneficial effects of the display panels provided by the embodiments of the present disclosure. For details, refer to the specific description of the display panels in the above embodiments, which will not be repeated here. The foregoing are detailed descriptions of the present disclosure in combination with specific embodiments. It is to be noted that the specific embodiments of the present disclosure are not limited to these descriptions. For a person skilled in the art, some specific deductions or substitutions may be made without departing from the principle of the present disclosure, which should be considered as falling within the protection scope of the present disclosure.

What is claimed is

1. A display panel, comprising:
a substrate;
a light-emitting unit layer disposed on one side of the substrate, the light-emitting unit layer including a plurality of main pixels and a plurality of auxiliary pixels; and
an auxiliary functional layer disposed on a side of the light-emitting unit layer away from the substrate, wherein:
the auxiliary function layer includes a first function part, and the first function part is arranged corresponding to an auxiliary pixel, and
in a first state, at least a portion of the first functional component is light-shielding.

2. The display panel according to claim 1, wherein the first functional component includes an electrochromic material.

3. The display panel according to claim 1, wherein:
the display panel further comprises a second state;
the first functional component is in a light-shielding state in the first state; and
the first functional component is in a transparent state in the second state.

4. The display panel according to claim 1, wherein, in the first state, at least a portion of the first functional component is in a transparent state.

5. The display panel according to claim 1, wherein the auxiliary pixel is a white light pixel.

6. The display panel according to claim 1, wherein the display panel satisfies W=2×H×tan θ, wherein W is a distance between adjacent first functional components, H is a distance from the light-emitting unit layer to a top of the first functional component, and θ is an anti-peeping angle.

7. The display panel according to claim 1, wherein multiple auxiliary pixels are arranged at intervals around a main pixel.

8. The display panel according to claim 1, further comprising a color resist layer, wherein the color resist layer is disposed on a side of the light-emitting unit layer away from the substrate.

9. The display panel according to claim 8, wherein the color resist layer includes a main color resist, and the main color resist corresponds to a main pixel.

10. The display panel according to claim 8, wherein the color resist layer includes an auxiliary color resist, and the auxiliary color resist corresponds to the auxiliary pixel.

11. The display panel according to claim 10, wherein a color of the auxiliary color resist is different from a color of an adjacent main pixel.

12. The display panel according to claim 1, wherein the auxiliary functional layer further includes a second functional component, and the second functional component is a light-shielding layer, and the second functional component exposes a main pixel.

13. The display panel according to claim 12, wherein the second functional component overlaps with the first functional component.

14. The display panel according to claim 12, wherein the second functional component is disposed on at least one side wall of the first functional component.

15. The display panel according to claim 12, wherein the second functional component is disposed in at least one opening formed by the first functional component.

16. The display panel according to claim 1, wherein the display panel further includes a touch function layer, and the touch function layer is disposed on a side of the light-emitting unit layer away from the substrate.

17. The display panel according to claim 16, wherein the touch function layer includes at least one touch electrode layer, and the at least one touch electrode layer is disposed on a side of the first function part away from the substrate.

18. The display panel according to claim 16, wherein the first functional component includes an electrochromic material, the touch functional layer includes at least one touch electrode layer, the first functional component includes a control electrode layer disposed on at least one side of the electrochromic material, and at least one of the touch electrode layers is in the same layer as at least one control electrode layer.

19. The display panel according to claim 1, wherein:
at least two main pixels of different colors are arranged alternately in a first direction or a second direction to form a main pixel array;
the auxiliary pixel is disposed between adjacent main pixels in the first direction or the second direction; and
the first direction intersects with the second direction.

20. A display device, comprising a display panel, and the display panel including:
a substrate;
a light-emitting unit layer disposed on one side of the substrate, the light-emitting unit layer including a plurality of main pixels and a plurality of auxiliary pixels; and
an auxiliary functional layer disposed on a side of the light-emitting unit layer away from the substrate, wherein:
the auxiliary function layer includes a first function part, and the first function part is arranged corresponding to an auxiliary pixel, and
in a first state, at least a portion of the first functional component is light-shielding.
